(19) United States
(12) Patent Application Publication
(10) Pub. No.: US 2023/0034561 A1
(43) Pub. Date: Feb. 2, 2023

(54) AMMONIA ABATEMENT FOR IMPROVED ROUGHING PUMP PERFORMANCE

(71) Applicant: Lam Research Corporation, Fremont, CA (US)

(72) Inventors: Gishun Hsu, Fremont, CA (US); Krishna Birru, Fremont, CA (US); Kevin Madrigal, Santa Cruz, CA (US)

(21) Appl. No.: 17/758,530

(22) PCT Filed: Jan. 6, 2021
(86) PCT No.: PCT/US2021/012363

§ 371 Date: Jul. 8, 2022

Related U.S. Application Data
(60) Provisional application No. 62/959,735, filed on Jan. 10, 2020.

(51) Int. Cl. C23C 16/448; C23C 16/34; C23C 16/44

(52) U.S. Cl. CPC C23C 16/448; C23C 16/34; C23C 16/4412

(57) ABSTRACT

In a process chamber connected with a process roughing pump via a pump foreline, pumping from the process chamber to the foreline ammonia and a deposition precursor, introducing into the foreline hydrogen fluoride gas to react with the ammonia to form ammonium fluoride, and maintaining the process roughing pump and pump foreline at at least the ammonium fluoride sublimation temperature during the pumping provides ammonia abatement for improved roughing pump performance.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in their entireties and for all purposes.

### BACKGROUND

Ammonia (NH₃) is frequently used as a co-reactant in various semiconductor processing operations. Ammonia can react with various deposition precursors, such as transition metal (e.g., tungsten, molybdenum, etc.) and silicon containing vapor deposition precursors, to form irreversible solids in the roughing pump used to pump or purge depositions reactant gases from a process chamber. These irreversible solids can adversely affect the roughing pump and tool throughput, and it is therefore desirable to mitigate the formation of these irreversible solids in the roughing pump.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

In some embodiments, a method may be provided. The method may include in an apparatus comprising a process chamber connected with a process roughing pump via a pump foreline, pumping from the process chamber to the foreline ammonia and a deposition precursor, introducing into the foreline hydrogen fluoride gas to react with the ammonia to form ammonium fluoride, and maintaining the process roughing pump and pump foreline at at least the ammonium fluoride sublimation temperature during the pumping.

In some embodiments, the process roughing pump and pump foreline may be maintained at a temperature of at least 100° C. during the pumping.

In some embodiments, the hydrogen fluoride may be introduced to the pump foreline in an amount at least stoichiometrically equal to the amount of ammonia pumped to the foreline.

In some such embodiments, the hydrogen fluoride may be introduced to the pump foreline in a ratio of about 1.1 hydrogen fluoride to 1 ammonia.

In some such embodiments, the hydrogen fluoride flow may be about 700 to 800 SCCM.

In some embodiments, the deposition precursor may include a transition metal species.

In some embodiments, the deposition precursor may include a transition metal halide.

In some embodiments, the deposition precursor may include tungsten fluoride.

In some embodiments, the deposition precursor may include tungsten chloride.

In some embodiments, the deposition precursor may include molybdenum fluoride.

In some embodiments, the deposition precursor may include molybdenum chloride.

In some embodiments, the deposition precursor may include a silicon-containing species.

In some embodiments, the deposition precursor may include a silicon halide.

In some embodiments, the deposition precursor may include a silicon chloride.

In some embodiments, the deposition precursor may include a silicon bromide.

In some embodiments, the deposition precursor may include a silicon iodide.

In some embodiments, the apparatus may further include a process exhaust abatement device connected with the process roughing pump via an exhaust line, and the exhaust line may be maintained at at least the ammonium fluoride sublimation temperature during the pumping.

In some such embodiments, the exhaust line may be maintained at a temperature of at least 100° C. during the pumping.

In some such embodiments, the ammonium fluoride may desublimate as solid ammonium fluoride and may be captured in the process exhaust abatement device for removal from the apparatus.

In some further embodiments, the removal of the solid ammonium fluoride may include dissolving the solid ammonium fluoride in the process exhaust abatement device in an aqueous solution.

In some embodiments, the pump foreline may further include a mixing area, and the hydrogen fluoride gas may be introduced into the foreline at or upstream of the mixing area such that the hydrogen fluoride mixes and reacts with the ammonia to form the ammonium fluoride prior to entering the process roughing pump.

In some embodiments, the maintaining the process roughing pump and pump foreline at at least the ammonium fluoride sublimation temperature during the pumping may include flowing a heated gas into the pump foreline and/or into the process roughing pump.

In some such embodiments, the heated gas may include nitrogen or argon.

In some embodiments, the maintaining the process roughing pump and pump foreline at at least the ammonium fluoride sublimation temperature during the pumping may include causing one or more heating elements to heat the pump foreline and/or the process roughing pump.

In some embodiments, an apparatus may be provided. The apparatus may include a process chamber connected with a process roughing pump via a pump foreline, a deposition precursor and ammonia gas source connected with the process chamber, a hydrogen fluoride gas source connected with the process roughing pump, gas flow-control hardware associated with the gas sources, and a controller having a processor and a memory. The processer and the memory are communicatively connected with one another, the processor is at least operatively connected with the flow-control hardware, and the memory stores computer-executable instructions for causing the process roughing pump to pump ammonia and a deposition precursor from the process chamber to the pump foreline, causing hydrogen fluoride gas to be introduced into the foreline to react with the ammonia to form ammonium fluoride, and causing the process roughing pump and the pump foreline to be maintained at at least the ammonium fluoride sublimation temperature during the pumping.

In some embodiments, the apparatus may further include a process exhaust abatement device connected with the process roughing pump via an exhaust line, and the memory stores computer-executable instructions for causing the exhaust line to be maintained at at least the ammonium fluoride sublimation temperature during the pumping.

In some embodiments, the pump foreline may further include a mixing area, and the memory further stores computer-executable instructions for introducing the hydrogen fluoride gas into the foreline at or upstream of the mixing area such that the hydrogen fluoride mixes and reacts with the ammonia to form the ammonium fluoride prior to entering the process roughing pump.

In some embodiments, the hydrogen fluoride gas may be connected to the process roughing pump via a connection to the pump foreline between the process chamber and the process roughing pump.

In some embodiments, the apparatus may further include a throttle valve connected to the pump foreline and configured to control gas flow through the pump foreline, and the hydrogen fluoride gas may be connected to the pump foreline between the throttle valve and the process roughing pump.

In some embodiments, the causing the process roughing pump and the pump foreline to be maintained at at least the ammonium fluoride sublimation temperature during the pumping may include causing a heated gas to be flowed into the pump foreline, into the process roughing pump, or into the pump foreline and the process roughing pump.

In some such embodiments, the heated gas may include nitrogen or argon.

In some embodiments, the apparatus may include one or more heating elements configured to heat the pump foreline to at least the ammonium fluoride sublimation temperature, and the causing the process roughing pump and the pump foreline to be maintained at at least the ammonium fluoride sublimation temperature during the pumping may include causing the one or more heating elements to heat the pump foreline to at least the ammonium fluoride sublimation temperature.

### BRIEF DESCRIPTION OF THE DRAWINGS

The various implementations disclosed herein are illustrated by way of example, and not by way of limitation, in the figures of the accompanying drawings, in which like reference numerals refer to similar elements.

FIG. 1 depicts a process flow for one aspect of the present disclosure.

FIG. 2 depicts a simplified schematic of an apparatus.

FIG. 3 depicts a more specific architecture of a particular example of an apparatus.

FIG. 4A illustrates a schematic representation of an apparatus for processing a partially fabricated semiconductor substrate in accordance with certain embodiments.

FIG. 4B shows another example plasma reactor that may be used to deposit or etch materials in accordance with certain semiconductor fabrication processes.

### DETAILED DESCRIPTION

Ammonia (NH₃) is frequently used as a co-reactant in various semiconductor processing operations, such as metal nitride or silicon nitride deposition processes. However, ammonia can react with various deposition precursors, such as transition metal (e.g., tungsten, molybdenum, etc.) and silicon containing vapor deposition precursors, to form irreversible solids in the roughing pump used to pump or purge depositions reactant gases from a process chamber. This can dramatically shorten the life of the roughing pump without excessively short periodic maintenance (PM) cycles. Short PM cycles result in decreased tool uptime and therefore reduced throughput.

A current ammonia mitigation technology is to react the ammonia with excess fluorine, generated from nitrogen trifluoride (NF₃) with a remote plasma source (e.g., MKS Astron). However, introducing fluorine to process streams containing high levels of hydrogen (H₂) or high levels of silane (SiH₄) or some other silicon-based and/or hydrogen-containing precursors can produce a highly exothermic reaction, which results in an undesirable hazard.

This challenge can be addressed by introducing hydrogen fluoride (HF) gas into the foreline of the roughing pump to react with ammonia (NH₃). The reaction of HF with NH₃ forms ammonium fluoride (NH₄F). The reaction is a not highly exothermic, so this hazard is not created. And HF does not react with H₂- or silane-based precursors.

NH₄F is a solid at room temperature. However, the NH₄F solid sublimes at temperatures of 100° C. or higher. With the appropriate heating of the pump foreline, pump and pump exhaust line, the accumulation of NH₄F solids can be controlled so that the deposition precursors pass through the pump and can be captured and removed from the system in an abatement device.

This approach prevents ammonia from reacting with deposition precursors to form irreversible solids in the pump, which increases life of the pump and lengthens the time between PM cycles.

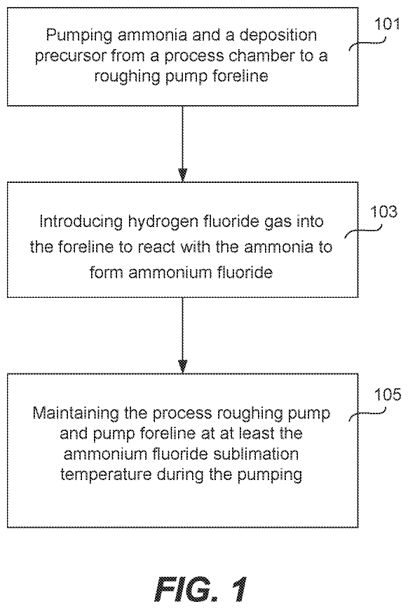

Referring to FIG. 1, a process flow is depicted for one aspect of the present disclosure, a method conducted in an apparatus having a process chamber connected with a process roughing pump via a pump foreline. At 101, ammonia and a deposition precursor are pumped from the process chamber to the foreline, such as upon pumping down or purging the process chamber following a deposition operation conducted in the process chamber. The ammonia and deposition precursor may be among other process gases pumped from the chamber. The deposition precursor may include a transition metal species, such as a transition metal halide. For example, the deposition precursor may include tungsten halide, such as tungsten or molybdenum chloride or fluoride. Other deposition precursors may include a silicon-containing species, such as a silicon halide, for example, silicon chloride, bromide or iodide. And contemplated deposition precursors may also include other elements, such as oxygen, nitrogen, etc., that are commonly incorporated in films deposited in semiconductor fabrication operations. Some samples process chemistries include:
WF₆+NH₃
MoX, where X includes a halide+NH₃+H₂
SiH₂X₂/SiHX₃/SiX₄, where X includes a halide+NH₃

Referring again to FIG. 1, at 103, hydrogen fluoride gas is introduced into the foreline to react with the ammonia to form ammonium fluoride. The hydrogen fluoride may be introduced to the pump foreline in an amount at least stoichiometrically equal to the amount of ammonia pumped to the foreline. For example, the hydrogen fluoride may be introduced to the pump foreline in a ratio of about 1.1 hydrogen fluoride to 1 ammonia. In a particular example, a suitable hydrogen fluoride flow rate may be about 700 to 800 standard cubic centimeters per minute (SCCM).

Referring again to FIG. 1, at 105, the process roughing pump and pump foreline are maintained at at least the ammonium fluoride sublimation temperature during the pumping so that the ammonium fluoride can pass to and through the pump in the gas phase to prevent fouling of the pump. For example, the process roughing pump and pump foreline may be maintained at a temperature of at least 100° C. during the pumping. In some embodiments, the process roughing pump and/or the pump foreline may be heated in order to maintain the temperature at at least 100° C. during pumping. This may include using one or more heating elements to heat the process roughing pump and/or the pump foreline. These heating elements may include resistive heaters or heating fluids positioned on or within the process roughing pump and/or the pump foreline. These heating elements are configured to heat the process roughing pump and/or the pump foreline to at least 100° C.

Additionally or alternatively, in some embodiments a heated gas may be flowed into the process roughing pump and/or the pump foreline in order to heat the process roughing pump and/or the pump foreline. This may be a heated inert gas, such as nitrogen or argon. In some implementations, this gas may be heated by one or more heaters configured to heat this gas, which may include one or more heating elements, such as a resistive heater or fluid conduits through which a heated fluid flows, positioned on or within one or more gas lines through which the gas flows. In some instances, this heated gas may be flowed from a gas source into the pump foreline through a connection point along the pump foreline. In some embodiments, this heated gas may be co-flowed with the hydrogen fluoride gas into the foreline. As described below, the heated gas may be flowed into the process roughing pump.

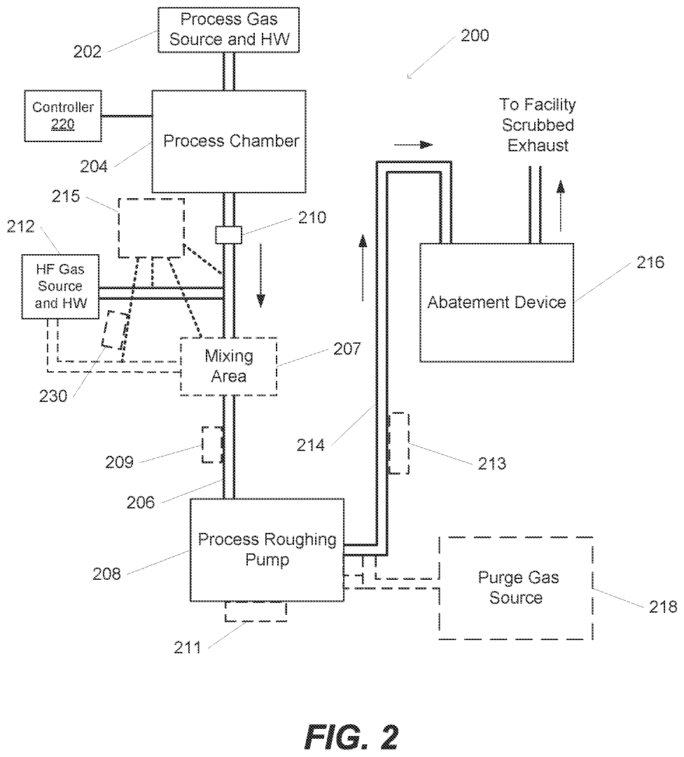

FIG. 2 depicts a simplified schematic of an apparatus such as described herein. The apparatus 200 includes a process chamber 204 connected with a process roughing pump 208 (e.g., a vacuum pump) via a pump foreline 206. A deposition precursor and ammonia gas source 202 (i.e., process gas source) is connected with the process chamber 204. As noted above, the ammonia and deposition precursor may be among other process gases pumped to and/or from the process chamber 204. Arrows indicate the direction of gas flow through the apparatus 200.

A hydrogen fluoride gas source 212 is connected with the pump 208 via the pump foreline 206. The foreline 206 may include a throttle valve 210 to control gas flow through the foreline 206 drawn by the process roughing pump 208. The process roughing pump 208 may have an associated pump purge gas source 218, such as a source of nitrogen (N₂) gas. This pump purge gas source 218 may be connected to the process roughing pump 208 and/or to an exhaust line 214 and configured to flow purge gas into the process roughing pump 208 and/or to the exhaust line 214. In some embodiments, this purge gas may be heated

The pump foreline may also optionally include a mixing area 207 in a configuration to provide for thorough reaction of the ammonia and HF in the event the a straight foreline is insufficient to achieve this. If the foreline 206 incorporates a mixing area 207, the HF gas source 212 may be connected with the foreline 206 via the mixing area 207. In either arrangement, the hydrogen fluoride gas is introduced into the foreline at or upstream of the mixing area, if present, and the pump such that the hydrogen fluoride mixes and reacts with the ammonia to form the ammonium fluoride prior to entering the process roughing pump.

As stated above, the process roughing pump and pump foreline are maintained at at least the ammonium fluoride sublimation temperature during the pumping. In some embodiments, the temperature may be maintained by using one or more heating elements to heat the process roughing pump and/or the pump foreline. In FIG. 2, a heating element 209 is illustrated on the pump foreline 206 and this heating element 209 is configured to heat the pump foreline 206 to at least 100° C. This heating element 209 also represents one or more heating elements, such as resistive heaters or heating fluids within fluid conduits positioned on or within the pump foreline 206. FIG. 2 also includes a second heating element 211 that is configured to heat the process roughing pump 208 to at least 100° C. This heating element 209 also represents one or more heating elements, such as resistive heaters or heating fluids within fluid conduits positioned on or within the process roughing pump 208.

As also stated above, in some embodiments, a portion of the pump foreline and/or the process roughing pump 208 may be heated to and maintained at at least the ammonium fluoride sublimation temperature during the pumping by flowing a heating gas from another gas source 215, such as a heated nitrogen or argon, into the pump foreline at a location between the process chamber 204 and the process roughing pump 208. This may include a point upstream or downstream from the connection point of the hydrogen fluoride into the pump foreline 206. In some instances, this heating gas may be co-flowed with the hydrogen fluoride into the pump foreline 206. In some embodiments, the other gas source 215 may be purge gas source 218 described herein such that purge gas source 218 may be configured to flow heated purge gas. In some implementations, this heating gas may be heated using another heater 230 configured to heat this gas, which may include one or more heating elements, such as a resistive heater or fluid conduits through which a heated fluid flows, positioned on or within one or more gas lines through which the gas flows. Although this heater 230 is illustrated on one gas line, it may be considered positioned on or within any gas line or gas plenum.

In some implementations that use a heated gas flowed from the additional gas source 215, the heating gas may be flowed into the line connected the hydrogen fluoride to the mixing area 207, into the foreline 206 upstream or downstream of the mixing area 207, or into the mixing area 207. This heated gas may maintain the portion of the foreline 206 between the mixing area 207 and the process roughing pump 208, and/or the process roughing pump at a temperature at at least the ammonium fluoride sublimation temperature, such as at least 100° C.

The apparatus 200 further includes gas flow-control hardware associated with the gas sources 202 and 212 and, and a controller 220 having a processor and a memory. The processer and the memory are communicatively connected with one another, the processor is at least operatively connected with the flow-control hardware, and the memory stores computer-executable instructions for conducting the at least the method operations described above with reference to FIG. 1 and elsewhere herein.

The apparatus 200 depicted in FIG. 2 further includes a process exhaust abatement device 216 connected with the process roughing pump 208 via an exhaust line 214. In one implementation of a method in accordance with this disclosure, the exhaust line 214 is maintained at at least the ammonium fluoride sublimation temperature during the pumping of gases through the apparatus, including the pumping of ammonium fluoride formed by the reaction of the ammonia and deposition precursor from the process chamber 204 in the foreline 206 and through the pump 208 and exhaust line 214 to the abatement device 216. For example, the exhaust line may be maintained at a temperature of at least 100° C. during the pumping. Similar to above, in some embodiments the exhaust line may be heated in order to maintain its temperature at at least 100° C. during pumping. This may include using one or more heating elements, illustrated in FIG. 2 as optional element 213, to heat the exhaust line 214 and these one or more heating elements 213 may include resistive heaters or heating fluids positioned on or within the exhaust line 214. These one or more heating elements 213 are configured to heat the exhaust line to at least 100° C.

Further in this regard and as provided herein, an additional heated purge gas (e.g., N₂) source 215 may be provided to facilitate the purging of gases from the pump 208 through the exhaust line 214 to the abatement device 216. As stated herein, this heated purge gas may be configured to heat the exhaust line 214 to at least the ammonium fluoride sublimation temperature, such as at least 100° C. In some embodiments, this heated purge gas may maintain the process roughing pump 208 and/or the exhaust line 213 at at least the ammonium fluoride sublimation temperature.

In the abatement device 216, the ammonium fluoride desublimates as solid ammonium fluoride and is captured for removal from the apparatus 200. For example, the removal of the solid ammonium fluoride may involve dissolving the solid ammonium fluoride in the process exhaust abatement device 216 in an aqueous solution. The controller 220 memory may store computer-executable instructions for conducting the operations described above in connection with pumping the gases through the pump 208 and exhaust line 214, to and through the abatement device 216, in the apparatus 200.

A suitable abatement device is known in the industry as a wet-burn-wet abatement unit. See, e.g., www.airgard.net/encompass.html. In such a device, a first section of the abatement unit is water-based, used to dissolve the ammonium fluoride. A second section of the abatement unit is burner/combustion-based to handle other effluents from the process chamber, such as chamber cleans. A third section of the abatement unit is wet-based, to capture the combustion by-products of the second section of the abatement unit.

Exhaust from the abatement device 216 may be directed to a facility scrubbed exhaust.

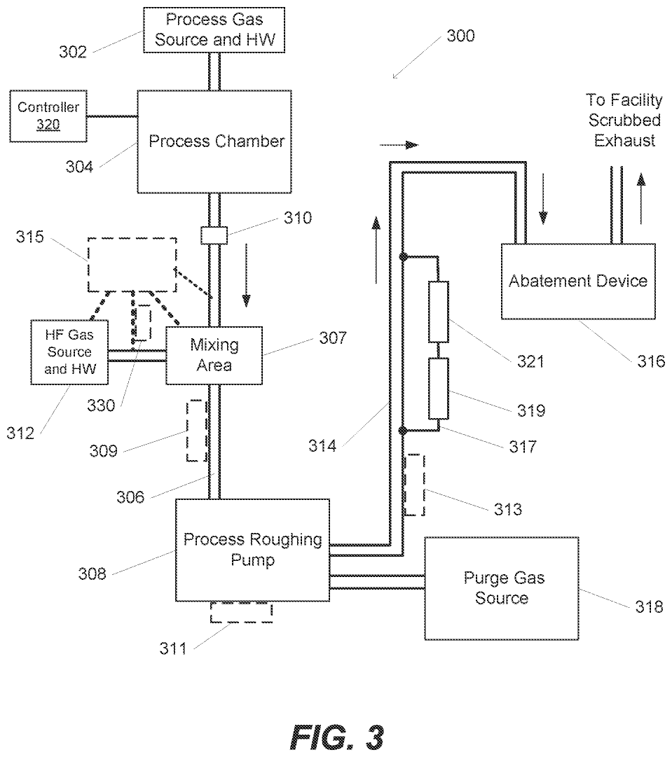

FIG. 3 depicts a more specific architecture of a particular example of an apparatus as described herein, to provide additional details of one specific embodiment of an implementation in accordance with the disclosure.

In FIG. 3, process chamber 304, the process gas source and hardware 302, and the throttle valve 310 are the same as in FIG. 2. Here, the mixing area 307 is included, is connected to the pump foreline 306, and is interposed between the throttle valve 310 and the process roughing pump 308. The hydrogen fluoride gas source 312 is connected with the foreline 306 via the mixing area 307, and the hydrogen fluoride gas is introduced into the foreline 306 at the mixing area 307. The hydrogen fluoride mixes and reacts with the ammonia to form the ammonium fluoride prior to entering the process roughing pump. Additional gas sources 315 may be used and connected to the hydrogen fluoride gas source 312, piping between the mixing area and the hydrogen fluoride gas source 312, and/or the mixing area 307 as illustrated with dashed optional lines.

One or more of these additional gases from gas sources 315 may assist with flowing the hydrogen fluoride into the mixing area 307 and/or to assist with maintaining the temperature of the mixing area 307, the foreline 306 between the mixing area 307 and the process roughing pump 308, and/or the process roughing pump 308. In some implementations, as discussed above with respect to gas source 215, a gas from gas source 315 may be a heated gas, such as a heated purge gas which may include argon or nitrogen. These gases may be heated in order to cause the temperature of the mixing area 307, the foreline 306 between the mixing area 307 and the process roughing pump 308, and/or the process roughing pump 308 at at least the ammonium fluoride sublimation temperature during the pumping, such as at least 100° C. These gases may include argon or nitrogen gas, for example. In some embodiments, the other gas source 315 may be purge gas source 318 described herein such that purge gas source 318 may be configured to flow heated purge gas.

In some embodiments, such as illustrated in FIG. 3, one or more heating elements 309 may be included to heat at least a part of the pump foreline 306. In some embodiments, alternatively or additionally, a gas from gas source 315 may be heated and flowed into the mixing area 307 to heat the mixing area 307, the pump foreline 306 between the mixing area and the process roughing pump 308, and/or the process roughing pump 308. This heating may be performed by one or more heating elements, or fluid conduits in which heated fluid flows, on or within gas lines, as represented by heating element 330.

As also seen in FIG. 3, the purge gas source 318 may be connected to the process roughing pump 308 and configured to flow purge gas into the process roughing pump 308. This gas may be heated nitrogen as described above. In some instances, apparatus 300 may also include a secondary gas line 317 connected to the exhaust line 314 and having a detector 319 and another pump 321. This detector 319 may be an infrared and/or gas detector configured to detect various aspects of the gases in the exhaust line 314, such as whether the ammonium fluoride is remaining in a gas state.

The remaining features of FIG. 3 may be the same as described with respect to FIG. 2.

Chamber Apparatus

The methods and apparatus described herein may be implemented and/or integrated with any suitable deposition chamber apparatus. Suitable apparatuses include various systems, e.g., ALTUS®, SPEED®, Striker®, and VECTOR®, available from Lam Research Corporation, Fremont, Calif., or any of a variety of other commercially available processing systems.

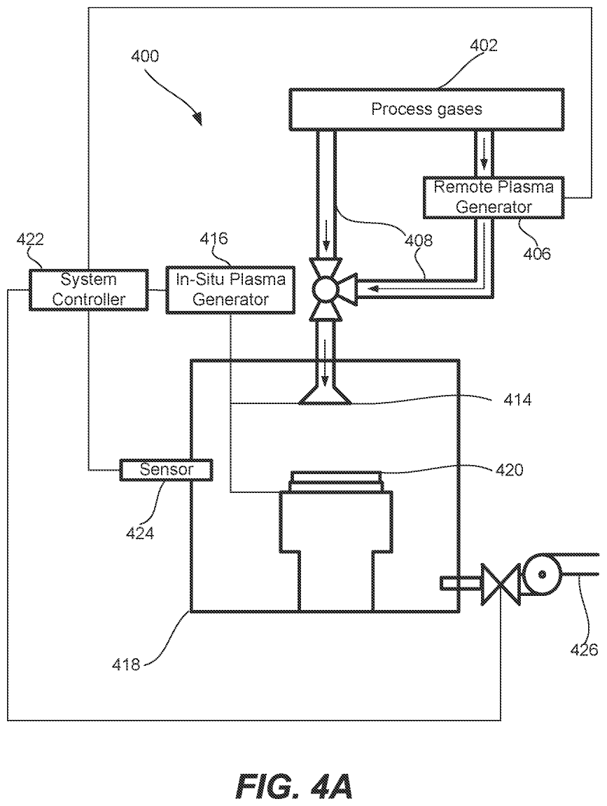

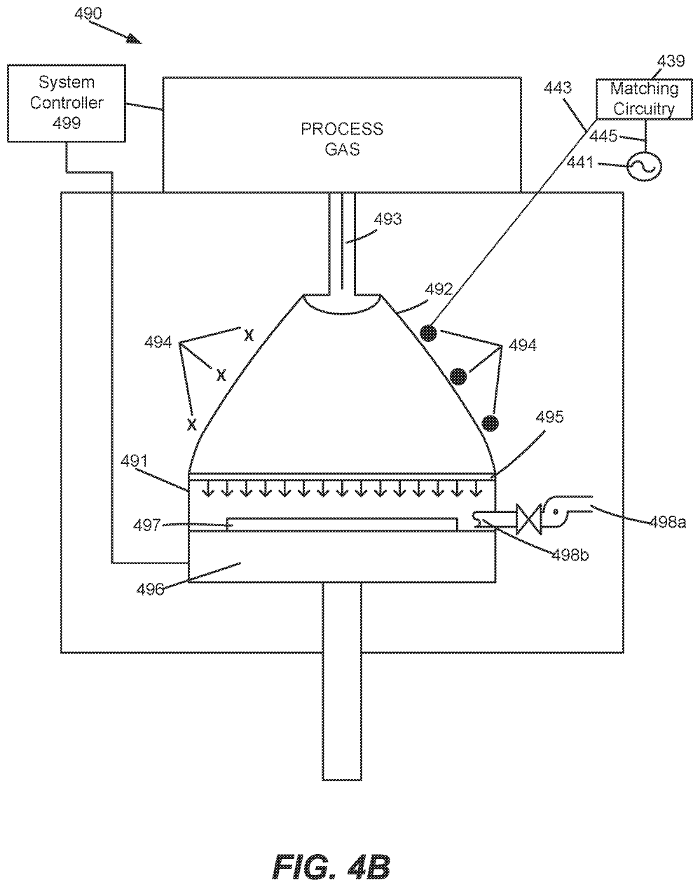

FIG. 4A illustrates a schematic representation of an apparatus 400 for processing a partially fabricated semiconductor substrate in accordance with certain embodiments. The apparatus 400 includes a chamber 418 with a pedestal 420, a showerhead 414, and an in-situ plasma generator 416. The apparatus 400 also includes a system controller 422 to receive input and/or supply control signals to various devices.

Process gases, including deposition and/or etch precursors, ammonia inert gases and others, are supplied from a source 402 which may be one or more storage tank or a gas box. Process gases may be activated with a remote plasma generator 406 before being introduced into the chamber 418. Any suitable remote plasma generator may be used. For example, a Remote Plasma Cleaning (RPC) unit, such as an ASTRON® unit available from MKS Instruments of Andover, Mass., may be used.

In certain embodiments, deposition precursors, etchant and other process gases can be flown from the source 402 through a remote plasma generator 406 and a connecting line 408 into the chamber 418, where the mixture is distributed through the showerhead 414. Alternatively, the remote plasma generator 406 may be absent or turned off while flowing the etchant into the chamber 418, for example, because activation of the process gases is not needed.

The showerhead 414 or the pedestal 420 typically may have an internal plasma generator 416 attached to it. In one example, the generator 416 is a High Frequency (HF) generator capable of providing between about 0 W and 10,000 W at frequencies between about 1 MHz and 100 MHz. In a more specific embodiment, the HF generator may deliver between about 0 W to 5,000 W at about 13.56 MHz.

The chamber 418 may include a sensor 424 for sensing various process parameters, such as degree of deposition and etching, concentrations, pressure, temperature, and others. The sensor 424 may provide information on chamber conditions during the process to the system controller 422. Examples of the sensor 424 include mass flow controllers, pressure sensors, thermocouples, and others. The sensor 424 may also include an infrared detector or optical detector to monitor presence of gases in the chamber and control measures.

Deposition and selective removal operations generate various volatile species that are evacuated from the chamber 418. Moreover, processing is performed at certain predetermined pressure levels the chamber 418. Both of these functions are achieved using a vacuum outlet 426, which may be a vacuum pump. An apparatus as described with reference to FIGS. 2 and 3 herein may be integrated here.

In certain embodiments, a system controller 422 is employed to control process parameters. The system controller 422 typically includes one or more memory devices and one or more processors. The processor may include a CPU or computer, analog and/or digital input/output connections, stepper motor controller boards, etc. Typically, there will be a user interface associated with system controller 422. The user interface may include a display screen, graphical software displays of the apparatus and/or process conditions, and user input devices such as pointing devices, keyboards, touch screens, microphones, etc.

In certain embodiments, the system controller 422 controls the substrate temperature, etchant flow rate, power output of the remote plasma generator 406, pressure inside the chamber 418 and other process parameters. The system controller 422 executes system control software including sets of instructions for controlling the timing, mixture of gases, chamber pressure, chamber temperature, and other parameters of a particular process. Other computer programs stored on memory devices associated with the controller may be employed in some embodiments.

The computer program code for controlling the processes in a process sequence can be written in any conventional computer readable programming language: for example, assembly language, C, C++, Pascal, Fortran or others. Compiled object code or script is executed by the processor to perform the tasks identified in the program. The system software may be designed or configured in many different ways. For example, various chamber component subroutines or control objects may be written to control operations of the chamber components used to carry out the described processes. Examples of programs or sections of programs for this purpose include process gas control code, pressure control code, and plasma control code.

The controller parameters relate to process conditions such as, for example, timing of each operation, pressure inside the chamber, substrate temperature, etchant flow rates, etc. These parameters are provided to the user in the form of a recipe and may be entered utilizing the user interface. Signals for monitoring the process may be provided by analog and/or digital input connections of the system controller 422. The signals for controlling the process are output on the analog and digital output connections of the apparatus 400.

FIG. 4B shows another example plasma reactor that may be used to deposit or etch materials in accordance with certain semiconductor fabrication processes. FIG. 4B schematically shows a cross-sectional view of an inductively coupled plasma apparatus 490, an example of which is a SPEED® Max reactor, produced by Lam Research Corporation of Fremont, Calif. Although ICP reactors are described herein, in some embodiments, it should be understood that capacitively coupled plasma reactors may also be used.

The inductively coupled plasma apparatus 490 includes an overall process chamber structurally defined by chamber walls 491 and a dome 492 for igniting a plasma. The chamber walls 491 may be fabricated from stainless steel or aluminum. Elements for plasma generation include a coil 494, which is positioned around the dome 492 and above the showerhead 495. In some embodiments, a coil is not used in disclosed embodiments. The coil 494 is fabricated from an electrically conductive material and includes at least one complete turn. The example of a coil 494 shown in FIG. 4B includes three turns. The cross-sections of coil 494 are shown with symbols, and coils having an “X” extend rotationally into the page, while coils having a “e” extend rotationally out of the page. Elements for plasma generation also include an RF power supply 441 configured to supply RF power to the coil 494. In general, the RF power supply 441 is connected to matching circuitry 439 through a connection 445. The matching circuitry 439 is connected to the coil 494 through a connection 443. In this manner, the RF power supply 441 is connected to the coil 494. Radio frequency power is supplied from the RF power supply 441 to the coil 494 to cause an RF current to flow through the coil 494. The RF current flowing through the coil 494 generates an electromagnetic field about the coil 494. The electromagnetic field generates an inductively coupled plasma within the dome 492. The physical and chemical interactions of various generated ions and radicals with the wafer 497 etch features on the semiconductor substrate or wafer 497.

Likewise, RF power supply 441 may provide RF power of any suitable frequency. In some embodiments, RF power supply 441 may be configured to control high- and low-frequency RF power sources independently of one another. Example low-frequency RF frequencies may include, but are not limited to, frequencies between 0 kHz and 500 kHz. Example high-frequency RF frequencies may include, but are not limited to, frequencies between 1 MHz and 2.45 GHz, or between 1.8 MHz and 2.45 GHz, or greater than about 13.56 MHz, or greater than 27 MHz, or greater than 40 MHz, or greater than 60 MHz. It will be appreciated that any suitable parameters may be modulated discretely or continuously to provide plasma energy for the surface reactions.

The RF power may be programmed to be ramped and/or pulsed during an etching operation performed in accordance with certain embodiments. For example, RF power may be ramped between an ON and OFF state, where the RF power during the OFF state is OW and the RF power during the ON state is between about 50 W and about 3000 W. RF power may be pulsed at a frequency between about 1 Hz and about 400 kHz, or between 1 Hz and about 100 KHz, or between about 10 Hz and about 100 kHz, or between about 100 Hz and about 10 kHz. The duty cycle may be between about 1% and about 99% or between about 10% and about 90%. The duration of RF power ON during a pulse may be between about 100 milliseconds and about 10 seconds, or between about 100 milliseconds and about 5 seconds.

Showerhead 495 distributes process gases toward substrate 497. In the embodiment shown in FIG. 4B, the substrate 497 is located beneath showerhead 495 and is shown resting on a pedestal 496. Showerhead 495 may have any suitable shape and may have any suitable number and arrangement of ports for distributing process gases to substrate 497.

A pedestal 496 is configured to receive and hold a substrate 497 upon which the etching is performed. In some embodiments, pedestal 496 may be raised or lowered to expose substrate 497 to a volume between the substrate 497 and the showerhead 495. It will be appreciated that, in some embodiments, pedestal height may be adjusted programmatically by a suitable computer controller 499.

In another scenario, adjusting a height of pedestal 496 may allow a plasma density to be varied during plasma activation cycles included in the process. At the conclusion of the process phase, pedestal 496 may be lowered during another substrate transfer phase to allow removal of substrate 497 from pedestal 496. In some embodiments, a position of showerhead 495 may be adjusted relative to pedestal 496 to vary a volume between the substrate 497 and the showerhead 495. Further, it will be appreciated that a vertical position of pedestal 496 and/or showerhead 495 may be varied by any suitable mechanism within the scope of the present disclosure. In some embodiments, pedestal 496 may include a rotational axis for rotating an orientation of substrate 497. It will be appreciated that, in some embodiments, one or more of these example adjustments may be performed programmatically by one or more suitable computer controllers 499.

Process gases (e.g. halogen-containing gases, NF₃, argon, WF₆, ammonia, nitrogen, etc.) may be flowed into the process chamber through one or more main gas flow inlets 493 positioned in the dome and/or through one or more side gas flow inlets (not shown). Likewise, though not explicitly shown, similar gas flow inlets may be used to supply process gases to a capacitively coupled plasma processing chamber. In some embodiments for a capacitively coupled plasma processing chamber, gas may be injected through a showerhead via the center and/or the edge of the showerhead. A vacuum pump, e.g., a one or two stage mechanical dry pump and/or turbomolecular pump 498a, may be used to draw process gases out of the process chamber 491 and to maintain a pressure within the process chamber 491. A valve-controlled conduit may be used to fluidically connect the vacuum pump to the process chamber 491 so as to selectively control application of the vacuum environment provided by the vacuum pump. This may be done employing a closed-loop-controlled flow restriction device, such as a throttle valve (not shown) or a pendulum valve (not shown), during operational plasma processing. Likewise, a vacuum pump and valve controlled fluidic connection to the capacitively coupled plasma processing chamber may also be employed. Volatile etching and/or deposition byproducts may be removed from the process chamber 491 through port 498b.

In some embodiments, a system controller 499 (which may include one or more physical or logical controllers) controls some or all of the operations of a process chamber 499. The system controller 499 may include one or more memory devices and one or more processors. In some embodiments, the apparatus 490 includes a switching system for controlling flow rates and durations when disclosed embodiments are performed. In some embodiments, the apparatus 490 may have a switching time of up to about 500 ms, or up to about 750 ms. Switching time may depend on the flow chemistry, recipe chosen, reactor architecture, and other factors.

In some implementations, the system controller 499 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be integrated into the system controller 499, which may control various components or subparts of the system or systems. The system controller 499, depending on the processing parameters and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the system controller 499 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication or removal of one or more layers, materials, metals, oxides, silicon, silicon dioxide, surfaces, circuits, and/or dies of a wafer.

The system controller 499, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the system controller 530 receives instructions in the form of data, which specify parameters for each of the processing steps to be performed during one or more operations. It should be understood that the parameters may be specific to the type of process to be performed and the type of tool that the controller is configured to interface with or control. Thus, as described above, the system controller 499 may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an ALD chamber or module, an ALE chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

### Results

The techniques and apparatuses herein were found to reduce ammonia at the roughing pump exhaust. In one experiment, the inventors found that before any hydrogen fluoride (HF) was flowed into the system, ammonia was flowing at a flowrate of about 1 SLPM and a concentration above 6,000 ppm. Once the HF was flowed into the system at about 1.1 SLPM, the ammonia concentration was reduced to less than 2,000 ppm, or reduced by about 85%.

### CONCLUSION

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the disclosed embodiments. Accordingly, the present embodiments are to be considered as illustrative and not restrictive, and the disclosed embodiments are not to be limited to the details given herein.

What is claimed is:

1. A method, comprising:
in an apparatus comprising a process chamber connected with a process roughing pump via a pump foreline,
pumping from the process chamber to the foreline ammonia and a deposition precursor;
introducing into the foreline hydrogen fluoride gas to react with the ammonia to form ammonium fluoride; and
maintaining the process roughing pump and pump foreline at at least the ammonium fluoride sublimation temperature during the pumping.

2. The method of claim 1, wherein the process roughing pump and pump foreline are maintained at a temperature of at least 100° C. during the pumping.

3. The method of claim 1, wherein the hydrogen fluoride is introduced to the pump foreline in an amount at least stoichiometrically equal to the amount of ammonia pumped to the foreline.

4. The method of claim 3, wherein the hydrogen fluoride is introduced to the pump foreline in a ratio of about 1.1 hydrogen fluoride to 1 ammonia.

5. The method of claim 3, wherein the hydrogen fluoride flow is about 700 to 800 SCCM.

6. The method of claim 1, wherein the deposition precursor comprises a transition metal species.

7. The method of claim 1, wherein the deposition precursor comprises a transition metal halide.

8. The method of claim 1, wherein the deposition precursor comprises tungsten fluoride.

9. The method of claim 1, wherein the deposition precursor comprises tungsten chloride.

10. The method of claim 1, wherein the deposition precursor comprises molybdenum fluoride.

11. The method of claim 1, wherein the deposition precursor comprises molybdenum chloride.

12. The method of claim 1, wherein the deposition precursor comprises a silicon-containing species.

13. The method of claim 1, wherein the deposition precursor comprises a silicon halide.

14. The method of claim 1, wherein the deposition precursor comprises a silicon chloride.

15. The method of claim 1, wherein the deposition precursor comprises a silicon bromide.

16. The method of claim 1, wherein the deposition precursor comprises a silicon iodide.

17. The method of claim 1, wherein the apparatus further comprises a process exhaust abatement device connected with the process roughing pump via an exhaust line, and the exhaust line is maintained at at least the ammonium fluoride sublimation temperature during the pumping.

18. The method of claim 17, wherein the exhaust line is maintained at a temperature of at least 100° C. during the pumping.

19. The method of claim 17, wherein the ammonium fluoride desublimates as solid ammonium fluoride and is captured in the process exhaust abatement device for removal from the apparatus.

20. The method of claim 19, wherein the removal of the solid ammonium fluoride comprises dissolving the solid ammonium fluoride in the process exhaust abatement device in an aqueous solution.

21. The method of claim 1, wherein the pump foreline further comprises a mixing area, and the hydrogen fluoride gas is introduced into the foreline at or upstream of the mixing area such that the hydrogen fluoride mixes and reacts with the ammonia to form the ammonium fluoride prior to entering the process roughing pump.

22. The method of claim 1, wherein the maintaining the process roughing pump and pump foreline at at least the ammonium fluoride sublimation temperature during the pumping includes flowing a heated gas into the pump foreline and/or into the process roughing pump.

23. The method of claim 22, wherein the heated gas comprises nitrogen or argon.

24. The method of claim 1, wherein the maintaining the process roughing pump and pump foreline at at least the ammonium fluoride sublimation temperature during the pumping includes causing one or more heating elements to heat the pump foreline and/or the process roughing pump.

25. An apparatus, comprising:
a process chamber connected with a process roughing pump via a pump foreline;
a deposition precursor and ammonia gas source connected with the process chamber;
a hydrogen fluoride gas source connected with the process roughing pump;
gas flow-control hardware associated with the gas sources; and
a controller having a processor and a memory,
wherein the processer and the memory are communicatively connected with one another, the processor is at least operatively connected with the flow-control hardware, and the memory stores computer-executable instructions for:
causing the process roughing pump to pump ammonia and a deposition precursor from the process chamber to the pump foreline,
causing hydrogen fluoride gas to be introduced into the foreline to react with the ammonia to form ammonium fluoride, and
causing the process roughing pump and the pump foreline to be maintained at at least the ammonium fluoride sublimation temperature during the pumping.

26. The apparatus of claim 25, wherein the apparatus further comprises a process exhaust abatement device connected with the process roughing pump via an exhaust line, and the memory stores computer-executable instructions for causing the exhaust line to be maintained at at least the ammonium fluoride sublimation temperature during the pumping.

27. The apparatus of claim 25, wherein the pump foreline further comprises a mixing area, and the memory further stores computer-executable instructions for introducing the hydrogen fluoride gas into the foreline at or upstream of the mixing area such that the hydrogen fluoride mixes and reacts with the ammonia to form the ammonium fluoride prior to entering the process roughing pump.

28. The apparatus of claim 25, wherein the hydrogen fluoride gas is connected to the process roughing pump via a connection to the pump foreline between the process chamber and the process roughing pump.

29. The apparatus of claim 25, further comprising a throttle valve connected to the pump foreline and configured to control gas flow through the pump foreline, wherein the hydrogen fluoride gas is connected to the pump foreline between the throttle valve and the process roughing pump.

30. The apparatus of claim 25, wherein the causing the process roughing pump and the pump foreline to be maintained at at least the ammonium fluoride sublimation temperature during the pumping includes causing a heated gas to be flowed into the pump foreline, into the process roughing pump, or into the pump foreline and the process roughing pump.

31. The apparatus of claim 30, wherein the heated gas comprises nitrogen or argon.

32. The apparatus of claim 25, further comprising one or more heating elements configured to heat the pump foreline to at least the ammonium fluoride sublimation temperature, wherein the causing the process roughing pump and the pump foreline to be maintained at at least the ammonium fluoride sublimation temperature during the pumping includes causing the one or more heating elements to heat the pump foreline to at least the ammonium fluoride sublimation temperature.
